(19) United States
(12) Patent Application Publication
(10) Pub. No.: US 2025/0251436 A1
(43) Pub. Date: Aug. 7, 2025

(54) SYSTEM FOR DETECTING SERIES ARC FAULTS IN ELECTRIC CABLING

(71) Applicant: Hamilton Sundstrand Corporation, Charlotte, NC (US)

(72) Inventors: Andrew BENN, Kenilworth (GB); Mital SHAH, Harrow (GB); Jaspreet Kaur MANN, Mississauga (CA)

(21) Appl. No.: 19/024,574

(22) Filed: Jan. 16, 2025

(30) Foreign Application Priority Data
Feb. 1, 2024 (EP) 24275004.0

(51) Int. Cl. G01R 31/12; G01R 19/10

(52) U.S. Cl. CPC G01R 31/1272; G01R 19/10

(57) ABSTRACT

A power supply system includes: a DC power supply, a load to be powered by the power supply, and a DC electrical conductor electrically connected at a first end to the power supply and at a second end to the load. The system further includes: a fault detection system configured to detect a series arc event in the DC electrical conductor, the fault detection system includes: a sense line conductor having a high impedance termination at the second end; a differential amplifier having a first input connected to the sense line conductor at a first terminal(S) and a second input connected to the DC electrical conductor at a second terminal (L), and an output providing a voltage differential output; and a comparator to compare the voltage differential output to a predetermined voltage differential threshold, the comparator providing a fault output dependent on the comparison.

### CROSS-REFERENCE TO RELATED APPLICATIONS

This application claims the benefit of European Patent Application No. 24275004.0 filed Feb. 1, 2024, the disclosure of which is incorporated herein by reference in its entirety.

### TECHNICAL FIELD

This disclosure is concerned with a system for detecting series arcing in electrical cabling such as in high power load supply systems. Such systems include, for example, motor drive or other high load drive systems in aircraft.

### BACKGROUND

Electrical systems include electrical cabling between a power supply and the load or loads to be driven. In some applications, such cabling may be very long and may be subject to wear or damage over its length, especially where the cabling is located in harsh environments subject to e.g. high temperature and/or vibrational variations or effects. Such wear or damage can cause arcing in the system. Parallel arcing, across cables, is relatively easy to detect using circuit breaker circuitry. Series arcing, along a cable, however, does not cause an increase in current and is, therefore, more difficult to detect, and may cause significant damage to the system and/or loads via thermal effects before current detection systems are able to disconnect the circuit.

Such electrical systems are finding application in more and more applications including more applications where high voltages are present. For example, there is a drive to increase the degree of electrical control in aircraft (so-called more electric aircraft (MEA) or all electric aircraft (AEA)). In such aircraft DC distribution voltages can be very high—in the range of e.g. 540 V dc, for driving high power loads such as aircraft motor drives. Failure or delay in detecting series arcing can have serious and even catastrophic consequences.

US 2022/0099724 proposes a system for detecting series arcing in electrical cabling using electrical circuitry to inject current into a monitoring line to eliminate the effect of a voltage drop in a main power line. This solution requires additional, complex circuitry in the sensing line (which, therefore, needs to have a corresponding large diameter). For high power systems, a significant power circuit would be required to provide a current controlled output at high voltage. Such a system is also vulnerable to the effects of noise in the dc voltage which can result in false arcing detection.

There is, therefore, a desire for an improved system for series arc detection.

### SUMMARY

According to the disclosure, there is provided power supply system comprising a DC power supply, a load to be powered by the power supply, and a DC electrical conductor electrically connected at a first end to the power supply and at a second end to the load, the system further comprising a fault detection system configured to detect a series arc event in the DC electrical conductor, the fault detection system comprising: a sense line conductor having a length the same as the DC electrical conductor and electrically connected at a first end to the power supply and at a second end to the load, the sense line having a high impedance termination at the second end; a differential amplifier having a first input connected to the sense line conductor at a first terminal and a second input connected to the DC electrical conductor at a second terminal, and an output providing a voltage differential output; and a comparator to compare the voltage differential output to a predetermined voltage differential threshold, the comparator providing a fault output dependent on the comparison.

In embodiments, a high-pass filter may be connected between the output of the differential amplifier and the comparator.

The comparator output may be configured to generate a fault indication in response to the voltage differential output exceeding the threshold.

The predetermined voltage differential threshold may be e.g. a set point or a dynamic threshold.

The fault detection system may be integrated with other circuitry of the load.

The DC electrical conductor may comprise a positive line and a negative line connected, respectively, to a positive and a negative terminal of the power supply.

In some embodiments, the power supply may be a power generator.

In some embodiments, the power supply may be a battery.

The load may be a motor drive, and a motor may be arranged to be driven by the motor drive. The motor drive may comprise switching inverter circuitry and may further comprise motor drive monitor and control circuitry.

The system may be an aircraft power supply system, and the load may be a motor drive configured to drive an aircraft motor

### BRIEF DESCRIPTION OF THE FIGURES

Examples of the system according to the disclosure will now be described with reference to the drawings. It should be noted that these are examples only and that variations are possible within the scope of the claims.

FIG. 1 is a simple diagram of a system according to the disclosure.

FIG. 2 shows arc detection circuitry according to the disclosure.

### DETAILED DESCRIPTION

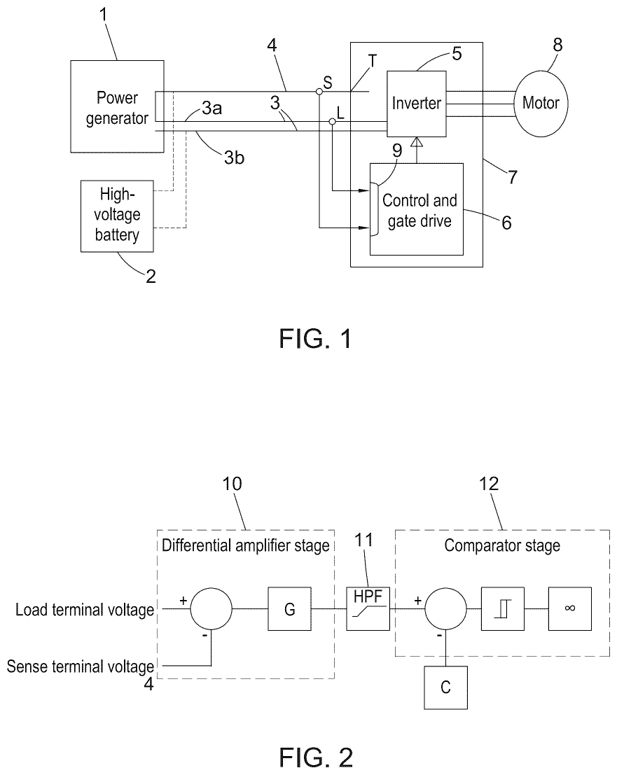

FIG. 1 shows a power drive system having a power supply 1,2 which may be a power generator 1 and/or a battery—e.g. high voltage battery 2 to provide a DC link voltage. A DC conductor or DC link main line 3 (referred to herein as the DC link harness 3) connects the battery/power generator to the load or loads to be driven e.g. a motor drive 7 for driving a motor 8. The DC link harness 3 includes a positive line connected to the positive terminal of the power supply and to a positive terminal of the load, and a negative line connected to the negative terminal of the power supply and to a negative terminal of the load. In this example, the motor drive 7 includes a switching inverter 5, powered by the DC supply, to drive the AC motor 8, as is known in the power supply or power converter art. In the example, the motor drive 7 also includes control and gate drive circuitry 6 to monitor and control the motor drive.

As described above, any arcing phenomenon on either the positive or the negative line along the length of the harness from power supply to load could cause faulty or no operation of the load (here, the motor drive and the motor).

To allow for reliable detection of a series arc, the system according to this disclosure adds a sense line, or sense harness 4, of the same length as the DC link harness, extending in parallel with the DC link harness from the power supply to the load. The sense line(s) may be provided for both DC positive and DC negative as part of a harness, or for just one of those lines. The sense line 4 has a high impedance termination T at the load end such that it does not draw current. Termination may be provided by a resistor network from the sense terminal to the load terminal of the opposite polarity. The resistor network may be made up of multiple high resistances to produce a high impedance termination. The high impedance will limit the current flow in the sense harness to a low value which allows for a small conductor cross-sectional area.

An arc detection circuit 9 is provided across the sense line 4, at a source terminal S and the DC link harness 3 at a load terminal L.

The arc detection circuit 9 may include a differential amplifier 10 having a first input connected to the sense line 4 at the source terminal S and a second input connected to the DC link harness at the load terminal L to provide an output indicative of the voltage differential between the sense line and the DC link harness. The output of the differential amplifier 10 may be provided to a high pass filter 11 to attenuate unwanted low frequency noise caused by e.g. inverter operation or load transients. It is only necessary, for arc detection, to look at high frequencies and so all of the DC components can be removed by the filter. A comparator 12 may then compare the filtered output with a predetermined threshold. The threshold may be a predetermined set point e.g. using a comparator, or can be set as a dynamic threshold using a programmable control system e.g. DSP or FPGA. If the output exceeds the threshold, this is indicative of a series arc. The output may be used to provide an alert or alarm or to disconnect the power circuit from the load e.g. by setting a system fault flag or in some other known manner for indicating fault detection.

In the example shown in FIG. 1, the arc detection circuit 9 is shown as part of the motor drive control circuitry block but in other examples, the arc detection circuitry may be provided as a separate block or may be integrated in other existing blocks.

In normal operation, the high frequency differential between terminal S and terminal L is negligible and below the threshold, so no fault will be reported and the system will continue to operate as normal. If a series arc event occurs, the DC voltage at the load terminal L will fluctuate due to anode and cathode voltage drop and a high frequency component will be observed at terminal L. As no arcing occurs on the sense line, no high frequency voltage variations are observed at terminal S. This then results in a high frequency, voltage differential between the terminals L and S which is detected by and provided as output from the differential amplifier 10 and which will, after filtering, exceed the predetermined threshold so provide a fault indication. Based on this indication, the system may take appropriate action as determined by the application and system design.

By reliably and quickly detecting series arcing in this way, this system can avoid false detection but can also cause system shut down before complete failure of or damage to the load and can allow preventative maintenance to be performed. The detection circuitry can be integrated into and, therefore, make use of existing circuitry present in typical load drive electronics. The reliable arc detection means that such power systems can be used in new and safety critical high voltage applications.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

While the present disclosure has been described with reference to an exemplary embodiment or embodiments, it will be understood by those skilled in the art that various changes may be made and equivalents may be substituted for elements thereof without departing from the scope of the present disclosure. In addition, many modifications may be made to adapt a particular situation or material to the teachings of the present disclosure without departing from the essential scope thereof. Therefore, it is intended that the present disclosure not be limited to the particular embodiment disclosed as the best mode contemplated for carrying out this present disclosure, but that the present disclosure will include all embodiments falling within the scope of the claims.

1. A power supply system comprising:
a DC power supply;
a load to be powered by the power supply;
a DC electrical conductor electrically connected at a first end to the power supply and at a second end to the load; and
a fault detection system configured to detect a series arc event in the DC electrical conductor, the fault detection system comprising:
a sense line conductor having a length the same as the DC electrical conductor and electrically connected at a first end to the power supply and at a second end to the load, the sense line having a high impedance termination at the second end;
a differential amplifier having a first input connected to the sense line conductor at a first terminal(S) and a second input connected to the DC electrical conductor at a second terminal (L), and an output providing a voltage differential output; and
a comparator to compare the voltage differential output to a predetermined voltage differential threshold, the comparator providing a fault output dependent on the comparison.

2. The system of claim 1, further comprising:
a high-pass filter connected between the output of the differential amplifier and the comparator.

3. The system of claim 2, wherein the comparator output is configured to generate a fault indication in response to the voltage differential output exceeding the threshold.

4. The system of claim 1, wherein the predetermined voltage differential threshold is a set point.

5. The system of claim 1, wherein the predetermined voltage differential threshold is a dynamic threshold.

6. The system of claim 1, wherein the fault detection system is integrated with other circuitry of the load.

7. The system of claim 1, wherein the DC electrical conductor comprises a positive line and a negative line connected, respectively, to a positive and a negative terminal of the power supply.

8. The system of claim 1, wherein the power supply is a power generator.

9. The system of claim 1, wherein the power supply is a battery.

10. The system of claim 1, wherein the load is a motor drive.

11. The system of claim 10, further comprising:
a motor arranged to be driven by the motor drive.

12. The system of claim 10, wherein the motor drive comprises switching inverter circuitry.

13. The system of claim 10, wherein the motor drive further comprises motor drive monitor and control circuitry.

14. The system of claim 1, in combination with aircraft and wherein the system is an aircraft power supply system.

15. The system of claim 14, wherein the load is a motor drive configured to drive an aircraft motor.
